(19) United States
(12) Patent Application Publication
(10) Pub. No.: US 2008/0076216 A1
(43) Pub. Date: Mar. 27, 2008

(54) Method to fabricate high-k/metal gate transistors using a double capping layer process

(76) Inventors: Sangwoo Pae, Beaverton, OR (US); Jose Maiz, Portland, OR (US); Chetan Prasad, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/527,263

(22) Filed: Sep. 25, 2006

(51) Int. Cl. H01L 21/336

(52) U.S. Cl. 438/257

(57) ABSTRACT

Semiconductor devices and methods to fabricate thereof are described. For an embodiment, a semiconductor device features a double capping layer. The double capping layer may include a first-capping layer and a second-capping layer. The first-capping layer protects a high-k gate dielectric film during a replacement gate process and the second-capping layer protects the first-capping layer during metal deposition. For other embodiments, the first-capping layer prevents the interaction between a polysilicon layer and a high-k gate dielectric film to prevent Vₜ-pinning of fabricated transistors.

### FIELD

Embodiments relate generally to the field of semiconductor manufacturing, and more specifically, to semiconductor devices and methods to fabricate thereof.

### BACKGROUND

Metal Oxide Semiconductor Field-Effect Transistors (MOSFETs) with very thin gate dielectrics, made from silicon dioxide, may experience gate leakage currents. In response, the trend is to form gate dielectrics from high-k dielectric materials. However, forming gate dielectrics from high-k dielectric materials instead of silicon dioxide can reduce gate leakage. When high-k gate dielectric films are formed, the films may have slight imperfect molecular structures. To repair these films, it may be necessary to anneal them at relatively high temperatures.

Certain high-k gate dielectric films may not be compatible with conventional polysilicon gate electrodes, and therefore it may be desirable to use metal gate electrodes in devices that include high-k gate dielectrics. Metal gate electrodes provide high performance relative to polysilicon. Oftentimes, the metals or alloys used in metal gate electrodes can not withstand the high temperatures necessary to anneal high-k dielectric films or activate dopants implanted in the source and drain regions. Likewise, a replacement gate process is used to facilitate high-k gate dielectric film annealing and dopant implantation without subjecting metal gate electrodes to high temperatures. During the replacement gate process, a high-k gate dielectric film may be exposed to a fab environment, which can significantly degrade the dielectric reliability of the high-k gate dielectric film.

### BRIEF DESCRIPTION OF THE DRAWINGS

The present invention is illustrated by way of example and not limitation in the figures of the accompanying drawings, in which like references indicate similar elements, and in which:

FIG. 1 shows a cross-section of a semiconductor device having a substrate, an interlayer dielectric, source and drain regions, a high-k gate dielectric layer, a first and second-capping layer, a metal gate electrode, and a set of spacers.

FIG. 2 shows a flowchart of an embodiment for a process for fabricating a semiconductor device.

FIGS. 3-16 are cross-sections of a semiconductor device illustrating a method for fabricating a semiconductor device according to an embodiment.

### DETAILED DESCRIPTION

Semiconductor devices and methods to fabricate thereof are described. For an embodiment, a semiconductor device features a double capping layer. For the embodiment, a double capping layer includes a first-capping layer and a second-capping layer; the first-capping layer protects a high-k gate dielectric film during a replacement gate process and the second-capping layer is used to protect the first-capping layer. For other embodiments, the first-capping layer prevents the interaction between a polysilicon layer and a high-k gate dielectric film to prevent Vₜ-pinning of fabricated transistors. For embodiments, the second-capping layer is an atomic deposition layer, which is well controlled and has a uniform thickness. For these embodiments, the second-capping layer is conformal and spans across all transistor gate lengths in the recessed gate regions. For embodiments, the cumulative thickness of the first and second-capping layer is optimized such that a metal gate electrode maintains control of the transistor threshold voltage.

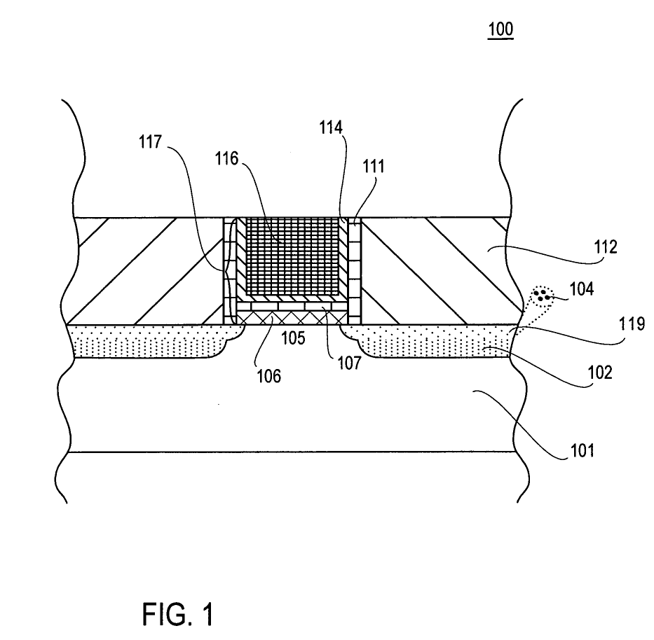

FIG. 1 shows a cross-section of a semiconductor device 100 having a substrate 101, an interlayer dielectric 112, source and drain regions 102, tip implants 119, a set of spacers 111, a gate dielectric layer 106, a first and second-capping layer 107, 114, and a metal gate electrode 116. For an embodiment, substrate 101 includes mono-crystalline silicon. For other embodiments, substrate 101 may include silicon-on-insulator (SOI) or any material that is used to make integrated circuits, passive, and/or active devices such as, but not limited to, germanium, indium antimonide, lead telluride, indium arsenide, indium phosphide, gallium arsenide, or gallium antimonide. Substrate 101 may include insulating materials that separate such active and passive devices from a conductive layer or layers that are formed on top of them. Additionally, substrate 101 may be doped with implants to a pre-determined polarity (p-type or n-type) and concentration to form n-wells or p-wells for a PMOS or NMOS transistor, respectively. Furthermore, the portion of the wells between the source and drain regions forms the channel region therein.

For an embodiment, source and drain regions 102, tip implant regions 119, and interlayer dielectric 112 may have properties characteristic to those known in the art of semiconductor manufacturing. For the embodiment, source and drain regions 102 may be doped to a pre-determined concentration and polarity (i.e. doped p-type or n-type). Additionally, interlayer dielectric 112 may comprise any suitable dielectric material known in the art such as, but not limited to, silicon dioxide, silicon nitride, polymers, another insulating material, or a combination of these materials.

FIG. 1 also illustrates gate dielectric layer 106, first and second-capping layers 107, 114, and metal gate electrode 116 stacked consecutively on each other to form a transistor gate stack 117. As shown, transistor gate stack 117 is adjacent to a set of spacers 111 such that implants for source and drain formation are offset from implants for tip implant region.

As shown in FIG. 1, first-capping layer 107 is disposed on gate dielectric layer 106. For the embodiment, gate dielectric layer 106 is a high-k gate dielectric film and for the embodiment, first-capping layer 107 isolates and protects high-k gate dielectric layer 106 during a replacement gate process. Accordingly, high-k gate dielectric layer 106 retains the characteristic high “k” dielectric property. Likewise, first-capping layer 107 may have any suitable thickness such that the dielectric property of high-k gate dielectric layer 106 is unaffected during a replacement gate process. For various embodiments, first-capping layer 107 has a composition that includes titanium nitride and tantalum nitride. First-capping layer 107 may have a thickness that ranges from 10 to 20 angstroms such that a metal gate electrode maintains control of a work function for a transistor gate electrode. For an embodiment, the thickness of first-capping layer 107 is approximately 15 angstroms.

FIG. 1 also shows second-capping layer 114 disposed on first-capping layer 107. For an embodiment, second-capping layer 114 protects first-capping layer 107 during a replacement gate process. Consequently, high-k gate dielectric layer 106 is also protected. For various embodiments second-capping layer 114 has a composition that includes titanium nitride and tantalum nitride. As shown in FIG. 1, second-capping layer 114 is adjacent to first-capping layer 107 and the sidewalls of metal gate electrode 116. Second-capping layer 114 need not be adjacent to the sidewalls of metal gate electrode 116 to adequately protect first-capping layer 107. However, for embodiments where second-capping layer 114 is adjacent to the sidewalls of metal gate electrode 116, second-capping layer 114 may provide extra containment of metal gate electrode 116 within transistor gate stack 117 and prevent exposure to interlayer dielectric 112. For alternate embodiments, second-capping layer 114 only covers first-capping layer 107.

Second-capping layer 114 may have a thickness that ranges from 5 to 15 angstroms such that a metal gate electrode maintains control of a work function for a transistor gate stack. For an embodiment, the thickness of second-capping layer 114 is approximately 5 angstroms.

The thickness of first and second-capping layers 107, 114 may be optimized such that the work function for transistor gate stack 117 is controlled by a metal gate electrode 116. Accordingly, the maximum combined thickness of first and second-capping layers 107, 114 is approximately 25 angstroms. For an embodiment, the combined thickness of first and second-capping layers 107, 114 is approximately 20 angstroms.

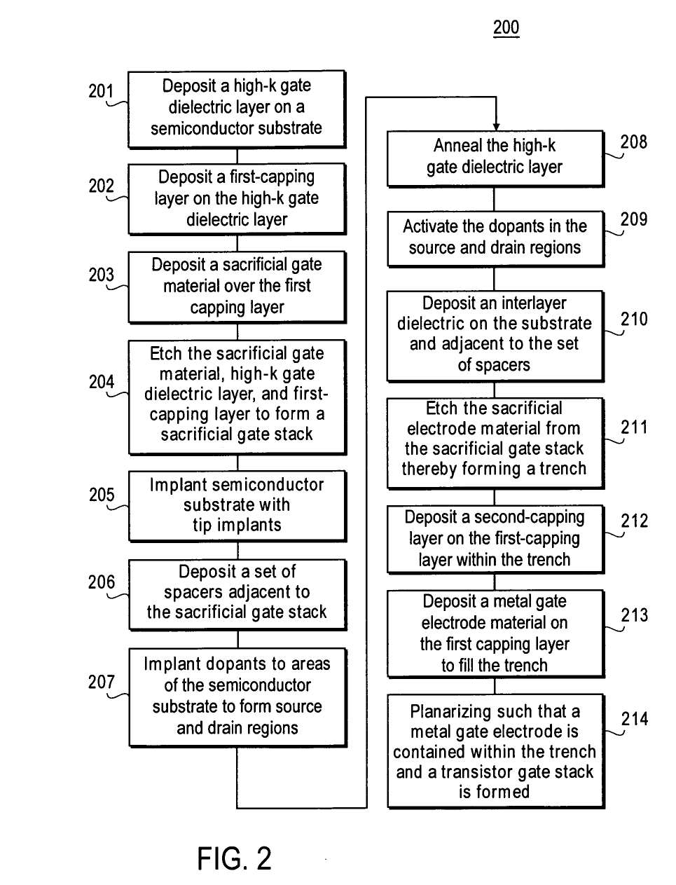

FIG. 2 shows a flowchart 200 of a process for fabricating a semiconductor device. The process may be defined as operations 201 through 214 as shown in FIG. 2.

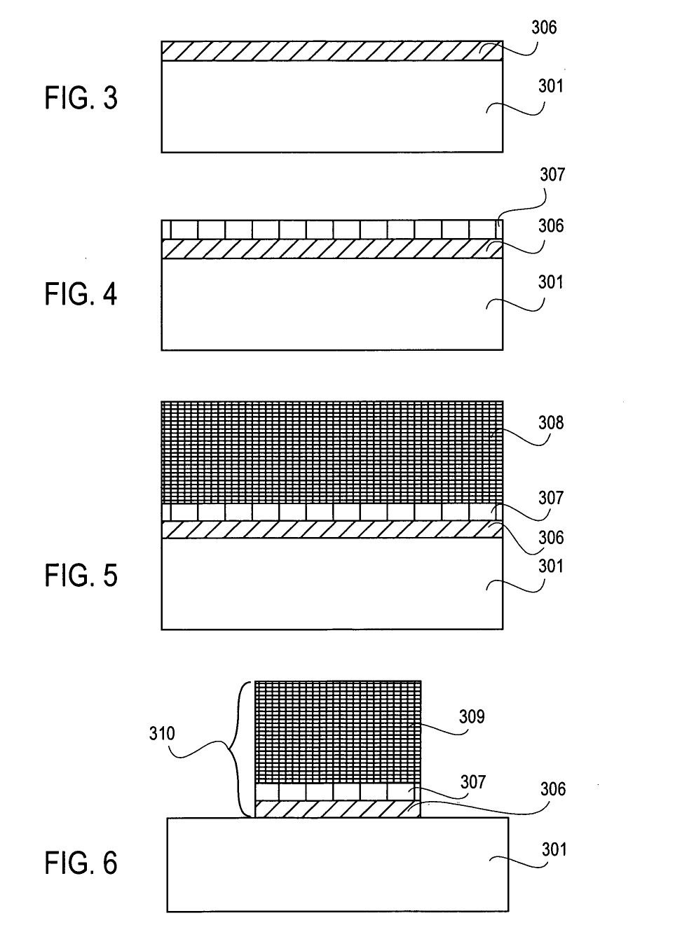

FIG. 3 shows a cross-sectional view of the start of a fabrication process for a semiconductor device according to a process embodiment defined by operation 201. For the embodiment, a gate dielectric layer 306 is formed over the top surface of semiconductor substrate 301. For the embodiment, gate dielectric layer 306 is a high-k gate dielectric film. High-k gate dielectric layer 306 may comprise any material such that the dielectric constant of high-k gate dielectric layer 306 exceeds 10. For various embodiments, high-k gate dielectric layer 306 comprises hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

High-k gate dielectric layer 306 can be formed over the top surface of semiconductor substrate 301 by any suitable method known in the art such as, but not limited to, chemical vapor deposition (CVD), physical vapor deposition (PVD), and atomic layer deposition (ALD). For an embodiment, high-k gate dielectric layer 306 is formed over semiconductor substrate 301 by an atomic layer deposition process (ALD). For one embodiment, high-k gate dielectric layer 306 is formed by exposing the semiconductor substrate 301 to alternating metal-containing precursors and oxygen-containing precursors until a layer, having the desired thickness, is formed. For example, hafnium tetrachloride, lanthanum trichloride, and water are exemplary metal and oxygen precursors that may be used to form high-k gate dielectric layer 306. For other embodiments, high-k gate dielectric layer 306 is formed by depositing and subsequently thermally oxidizing a metal layer on semiconductor substrate 301.

Typically, high-k gate dielectric layer 306 has a thickness that ranges from 3 to 60 angstroms. For an embodiment, the thickness of high-k gate dielectric layer 306 is approximately 20 angstroms.

Next, as shown in FIG. 4, a first-capping layer 307 is formed on high-k gate dielectric layer 306 according to operation 202. First-capping layer 307 may be formed of any suitable material that is selective to high-k gate dielectric layer 306 and provides adequate protection thereto. For various embodiments, titanium nitride and tantalum nitride are suitable materials from which first capping layer 307 are formed.

First-capping layer 307 may be formed on high-k gate dielectric layer 306 by any suitable method known in the art such as, but not limited to, ALD, CVD, or PVD (sputtering). For one embodiment, first-capping layer 307 and high-k gate dielectric layer 306 are formed in situ. That is, exposure of semiconductor substrate 301 to oxygen between formation of each layer is minimized, such as by forming and/or transferring the layers under vacuum or inert ambient. In particular, first-capping layer 307 is formed by a process in which high-k gate dielectric layer 306 is not exposed to oxygen. For one embodiment, high-k gate dielectric layer 306 and first-capping layer 307 are formed in the same chamber. In addition, first-capping layer 307 is typically deposited at a low temperature. For other embodiments, first-capping layer 307 is formed by a sputtering process.

First-capping layer 307 is formed to a thickness such that high-k gate dielectric layer 306 is adequately protected. Accordingly, first-capping layer 307 has a thickness that ranges from 10-20 angstroms. For an embodiment, the thickness of first-capping layer 307 is approximately 15 angstroms.

FIG. 5 shows the stage in the semiconductor device fabrication process after a sacrificial gate electrode material 308 is formed over first-capping layer 307 according to operation 203. Sacrificial gate electrode material 308 can serve as a mask for an underlying channel region during ion implantation for source and drain formation. Additionally, sacrificial gate electrode material 308 may sufficiently withstand high temperatures during high-k gate dielectric layer 306 anneal. Sacrificial gate electrode material 308 is termed “sacrificial” because it is removed during a subsequent replacement gate process. Sacrificial gate electrode material 308 may be deposited using well known techniques such as, for example, CVD. For one embodiment, sacrificial gate electrode material 308 includes polysilicon. In addition to polysilicon, sacrificial gate electrode material 308 may include any material such that a mask for an underlying channel region is achieved and such that sacrificial gate electrode material 308 can sufficiently withstand high temperatures during high-k gate dielectric layer 306 anneal.

Next, according to operation 204, the semiconductor device fabrication process continues by patterning sacrificial gate electrode material 308 using well known photolithography and etching processes to form sacrificial gate electrode 309. For the embodiment shown in FIG. 6, first-capping layer 307 and high-k gate dielectric layer 306 are also patterned by lithography-etch processes to form a sacrificial gate stack 310.

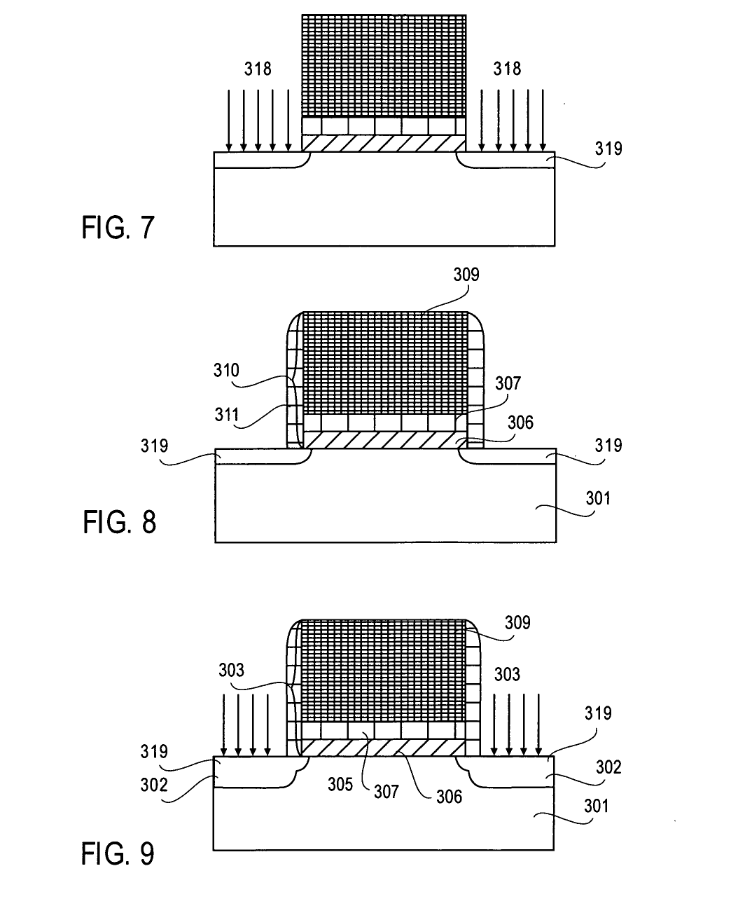

FIG. 7 shows the stage in the semiconductor device fabrication process after tip implant regions 319 are formed in semiconductor substrate 301 according to operation 205. For the embodiment shown, tip implant regions 319 are formed by tip implants 318 to pin dislocations present in semiconductor substrate 301 to avoid potential electrical shorts, and to form shallow, abrupt junctions which makes semiconductor device 300 more resistant to short-channel effects such as punch through.

FIG. 8 shows the stage in the semiconductor device fabrication process after spacers 311 are formed adjacent to the sides of sacrificial gate stack 310 according to operation 206. For embodiments, spacers 311 offset subsequently formed source and drain regions from tip implant regions 319. For an embodiment, spacers 311 are formed by blanket depositing a spacer material layer by a CVD process at relatively high temperatures and subsequently etching back the spacer material layer. For an embodiment, spacer 311 deposition occurs at a temperature of approximately 500° C.

Then, according to operation 207, the process continues by implanting 303 areas of substrate 301 to form source and drain regions 302 as shown in FIG. 9. For the embodiment shown, source and drain regions 302 are formed deeper in semiconductor substrate 301 than tip implant regions 319. Source and drain regions 302 may be doped positively (p-type) or negatively (n-type) to a desired concentration. For an embodiment, source and drain regions 302 are N⁺ doped and have a concentration of approximately 10¹⁸-10²⁰ atoms/cm³.

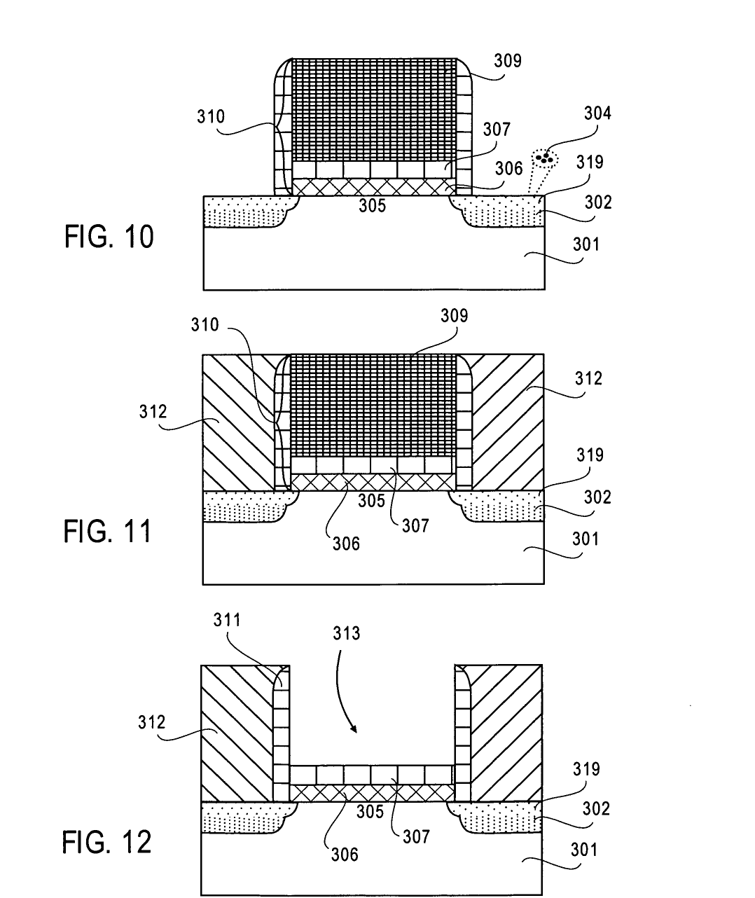

FIG. 10 shows the stage in the semiconductor device fabrication process after high-k gate dielectric layer 306 is annealed according to operation 208. For an embodiment, high-k gate dielectric layer 306 is annealed at a temperature greater than or equal to 600° C. As shown in FIG. 10, high-k gate dielectric layer 306 features intersecting-diagonal lines (as opposed to parallel-diagonal lines illustrated in the previous figures) to indicate the anneal. For an embodiment, annealing high-k gate dielectric layer 306 also activates implanted dopants 304 in source and drain regions 302 and tip implants 318 in tip implant regions 319. For other embodiments, annealing high-k gate dielectric layer 306 and activating implanted dopants 304 occur in separate process operations. For one embodiment when source and drain regions 302 are annealed independently from high-k gate dielectric layer 306 (operation 209), a rapid thermal anneal (RTA) process is used to activate the implanted dopants 304.

For embodiments that feature a high-k gate dielectric layer 306 process, high-k gate dielectric layer 306 may transition from a kinetic product state (or in situ state) to a thermodynamic product state upon anneal. The transition from a kinetic product to a thermodynamic product may cause unsaturated sites in the high-k gate dielectric layer 306 to become saturated. The resulting thermodynamic high-k gate dielectric layer 306 is typically more stable and consistent than the kinetic high-k gate dielectric layer 306.

As shown in FIG. 11, an interlayer dielectric 312 is deposited on the surface of semiconductor substrate 301 according to operation 210. Interlayer dielectric 312 can be blanket deposited over semiconductor substrate 301 and sacrificial gate stack 310 by various deposition techniques such as, but not limited to, chemical vapor deposition (CVD), plasma enhanced chemical vapor deposition (PECVD), spin-on, or sputtering. Subsequently, interlayer dielectric 312 is planarized using a chemical or mechanical polishing technique to expose the top surface of sacrificial gate electrode 309. For various embodiments, interlayer dielectric 312 may be any one, or a combination of, silicon dioxide, silicon nitride, polymer, or other insulating materials. Interlayer dielectric 312 may have any suitable thickness to isolate multiple transistors and metal lines. For various embodiments, interlayer dielectric 312 has a thickness that ranges from 600 to 2000 angstroms and for an embodiment, interlayer dielectric 312 is formed to a thickness of approximately 800 angstroms.

FIG. 12 illustrates the stage in the semiconductor device fabrication process after sacrificial gate electrode 309 is removed from sacrificial gate stack 310 according to a replacement gate process (operation 211). Accordingly, a trench 313 is exposed in the area from which sacrificial gate electrode 309 has been removed from sacrificial gate stack 310 as shown in FIG. 12. For an embodiment, a wet etching process comprising tetramethyl ammonium hydroxide (TMAH) is used to etch-remove sacrificial gate electrode 309 from sacrificial gate stack 310.

The process leaves, at a minimum, first-capping layer 307 and high-k gate dielectric layer 306 within trench 313. The high-k gate dielectric layer 306 that remains is an annealed, electrically-thin and intact dielectric.

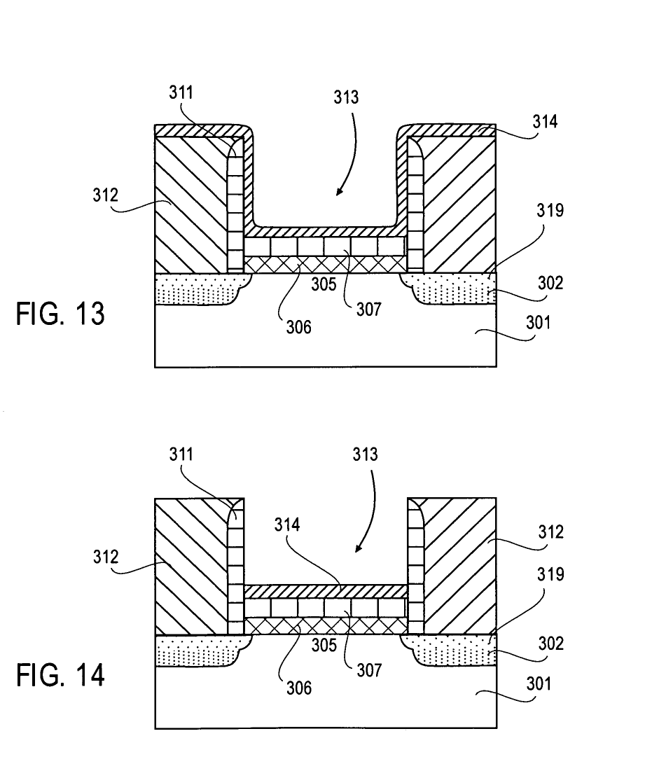

Next, a second-capping layer 314 is formed within trench 313 and on first-capping layer 307 according to operation 212, as shown in FIG. 13. Second-capping layer 314 protects first-capping layer 307 during subsequent dual metal gate processing steps, for example, during sulfuric chemistry clean processes. Second-capping layer 314 may be formed of any suitable material that is selective to first-capping layer 307 and provides adequate protection thereto. For various embodiments, second-capping layer 314 is formed from titanium nitride or tantalum nitride.

Second-capping layer 314 may be formed by any suitable process known in the art such as, but not limited to, CVD, PVD, and ALD. For an embodiment, second-capping layer 314 is formed by an ALD (atomic layer deposition) process. As shown in FIG. 13, an atomic layer deposition process forms a thin, uniform, and conformal second-capping layer throughout the sidewalls of trench 313 and on the top surface of interlayer dielectric 312. Second-capping layer 314 need not be adjacent to the sidewalls of trench 313 to adequately protect first-capping layer 307 during a replacement gate process. However, if second-capping layer 314 is adjacent to the sidewalls of trench 313, second-capping layer 314 may provide extra containment of a subsequently formed metal gate electrode to prevent exposure to interlayer dielectric 312.

For other embodiments, second-capping layer 314 is only present upon the base of trench 313. For example, FIG. 14 shows second-capping layer 314 disposed on first-capping layer 307 without being adjacent to the sidewalls of trench 313 as shown in FIG. 13.

As stated, second-capping layer 314 is formed to a thickness such that first-capping layer 307 is adequately protected. Accordingly, second-capping layer 314 has a thickness that ranges from 5-15 angstroms and for an embodiment the thickness of second-capping layer 314 is approximately 5 angstroms.

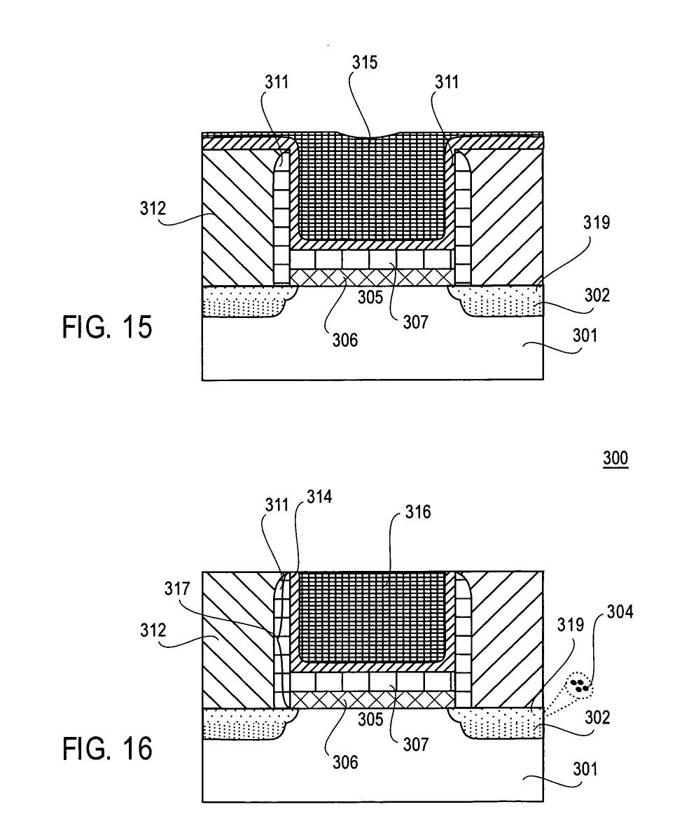

FIG. 15 illustrates the stage in the semiconductor device fabrication process after a metal gate electrode is formed in trench 313 according to operation 213. First, a metal gate material 315 is formed in trench 313. For various embodiments, metal gate electrode material has a composition that includes at least one of copper, ruthenium, palladium, platinum, cobalt, nickel, ruthenium oxide, tungsten, aluminum, titanium, tantalum, titanium nitride, tantalum nitride, hafnium, zirconium, a metal carbide, or a conductive metal oxide.

Metal gate material 315 may be formed in trench 313 by any suitable method known in the art such as, but not limited to, chemical or physical vapor deposition. For an embodiment, metal gate material 315 is formed in trench 313 by a CVD process. For the embodiment shown in FIG. 15, metal gate material 315 exceeds trench 313 such that a subsequent planarization process is needed to contain metal gate material 315 within trench 313.

As shown in FIG. 16, the semiconductor device fabrication process continues with a chemical mechanical polish such that metal gate material 315 is contained in trench 313 to form metal gate electrode 316.

The aforementioned planarization process may also be used to remove regions of second-capping layer 314 that exceed trench 313. For the embodiment shown in FIG. 16, a planarization process removes both metal gate material 315 and second-capping layer 314 that exceeds the confines of trench 313. Accordingly, a transistor gate stack 317 and a transistor device 300 is formed.

In the foregoing specification, the invention has been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

1. A device, comprising:
a substrate;
an interlayer dielectric disposed on a top surface of said substrate, wherein said interlayer dielectric comprises a first portion and a second portion;
a gate dielectric layer disposed between said first and second portions of said interlayer dielectric and over said substrate;
a first-capping layer disposed between said first and second portions of said interlayer dielectric and on said gate dielectric layer;
a second-capping layer disposed between said first and second portions of said interlayer dielectric and on said first-capping layer; and
a metal gate electrode disposed between said first and second portions of interlayer dielectric and on said second-capping layer;

2. The device of claim 1, wherein said second-capping layer is disposed on said first-capping layer and is adjacent to a sidewall of said metal gate electrode.

3. The device of claim 1 further comprising a source and drain region disposed within said substrate and on opposite sides of said metal gate electrode;
a channel region disposed within said substrate and between said source and drain regions.

4. The device of claim 1, wherein said gate dielectric layer is a high-k gate dielectric layer.

5. The device of claim 4, wherein said high-k gate dielectric layer comprises a material selected from the group consisting of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

6. The device of claim 1, wherein said first-capping layer comprises a material that is selected from the group consisting of titanium nitride and tantalum nitride.

7. The device of claim 1, wherein said second-capping layer comprises a material that is selected from the group consisting of titanium nitride and tantalum nitride.

8. The device of claim 1, wherein said metal gate electrode comprises a material selected from the group consisting of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

9. A semiconductor device, comprising:
a semiconductor substrate;
an interlayer dielectric disposed on a top surface of said substrate, wherein said interlayer dielectric comprises a first portion and a second portion;
a high-k gate dielectric layer disposed between said first and second portions of said interlayer dielectric and over said substrate;
a first-capping layer disposed between said first and second portions of interlayer dielectric and on said high-k gate dielectric layer;
an atomic deposition layer disposed between said first and second portions of said interlayer dielectric and on said first-capping layer;
a metal gate electrode disposed between said first and second portions of said interlayer dielectric and over said atomic deposition layer;
a source and drain region disposed within said substrate and adjacent to said interlayer dielectric and said set of spacers;
a channel region disposed within said substrate and adjacent to said high-k gate dielectric layer and said source and drain regions; and
a set of spacers adjacent to said high-k gate dielectric layer, first-capping layer, second-capping layer, and said metal gate electrode.

10. The semiconductor device of claim 9, wherein said atomic deposition layer is adjacent to a sidewall of said atomic deposition layer.

11. The semiconductor device of claim 9, wherein said first capping layer comprises a material that is selected from the group consisting of titanium nitride and tantalum nitride.

12. The semiconductor device of claim 9, wherein said atomic deposition layer comprises a material that is selected from the group consisting of titanium nitride and tantalum nitride.

13. The semiconductor device of claim 9, wherein the thickness of said first-capping layer ranges from 10 to 20 angstroms.

14. The semiconductor device of claim 9, wherein the thickness of said atomic deposition layer ranges from 5 to 15 angstroms.

15. The semiconductor device of claim 9, wherein the maximum combined thickness of said first capping layer and said atomic deposition layer is less than or equal to 25 angstroms.

16. A method, comprising
depositing a high-k gate dielectric layer on a semiconductor substrate,
depositing a first-capping layer on said high-k gate dielectric layer;
forming a sacrificial gate electrode material on said first-capping layer;
etching said high-k gate dielectric layer, first-capping layer, and said sacrificial gate electrode material to define a sacrificial gate stack;
depositing a set of spacers adjacent to said sacrificial gate stack;
implanting dopants in said semiconductor substrate to define a source and drain region;
depositing an interlayer dielectric on said semiconductor substrate and adjacent to said set of spacers;
etching said sacrificial gate electrode material to expose said first-capping layer and to define a trench; and
forming a second-capping layer within said trench and on said first-capping layer by an atomic layer deposition process.
filling said trench with a metal gate material to form a metal gate electrode.

17. The method of claim 16, further comprising polishing said substrate to form a planarized transistor gate stack.

18. The method of claim 16, wherein polishing said substrate comprises a chemical mechanical polish process.

19. The method of claim 16 further comprising annealing said high-k gate dielectric layer and activating said dopants in said source and drain region prior to forming said metal gate electrode.

20. The method of claim 16, wherein etching said sacrificial gate electrode from said trench comprises selectively wet etching said sacrificial gate in a tetramethyl ammonium hydroxide solution.

21. The method of claim 16, wherein said second-capping layer is conformally formed on a base and said sidewalls of said trench.

22. The method of claim 16, wherein said source and drain region is N⁺ doped and have a concentration of approximately 10¹⁸ atoms/cm³.
